(19) United States
(12) Patent Application Publication
(10) Pub. No.: US 2025/0259953 A1
(43) Pub. Date: Aug. 14, 2025

(54) SEMICONDUCTOR PACKAGE

(71) Applicant: Samsung Electronics Co., Ltd., Suwon-si (KR)

(72) Inventor: Junseo LEE, Suwon-si (KR)

(21) Appl. No.: 18/807,028

(22) Filed: Aug. 16, 2024

(30) Foreign Application Priority Data
Feb. 8, 2024 (KR) 10-2024-0019866

(51) Int. Cl. H01L 23/00; H01L 23/13; H01L 23/31; H01L 23/498

(52) U.S. Cl. CPC H01L 24/13; H01L 23/13; H01L 23/49822; H01L 24/16; H01L 23/3107; H01L 24/32; H01L 24/73; H01L 2224/13082; H01L 2224/13305; H01L 2224/13309; H01L 2224/13311; H01L 2224/13318; H01L 2224/13344; H01L 2224/13355; H01L 2224/1349; H01L 2224/16014; H01L 2224/16237; H01L 2224/32225; H01L 2224/73204

(57) ABSTRACT

A semiconductor package may include a package substrate having a first surface and a second surface, which are opposite to each other, and including a trench formed in the first surface, a substrate pad provided on the package substrate to cover a bottom surface of the trench, a conductive coupling pattern in contact with a top surface of the substrate pad, an anisotropic conductive pattern provided on the conductive coupling pattern and the substrate pad to fill the trench, the anisotropic conductive pattern including conductive capsules and a polymer layer enclosing the conductive capsules, a semiconductor chip mounted on the first surface of the package substrate, and a coupling pillar pattern provided between the package substrate and the semiconductor chip and connected to the conductive coupling pattern in the trench. A top surface of the anisotropic conductive pattern may be coplanar with the first surface of the package substrate.

### CROSS-REFERENCE TO RELATED APPLICATIONS

This U.S. non-provisional patent application claims priority under 35 U.S.C. § 119 to Korean Patent Application No. 10-2024-0019866, filed on Feb. 8, 2024, in the Korean Intellectual Property Office, the entire contents of which are hereby incorporated by reference.

### BACKGROUND OF THE INVENTION

The present disclosure relates to a semiconductor package, in particular, to a bump structure of a semiconductor package.

The demand for an electrode terminal structure with many pins and a small pitch is increasing rapidly in a semiconductor chip. To meet this demand, many studies are being conducted to reduce the size of the semiconductor chip. In general, the semiconductor chip includes electric connection terminals (e.g., solder balls or bumps), which are used for interconnection with an electronic device or a printed circuit board. To meet the afore-stated demand, it is necessary to reduce a pitch of the connection terminals in the semiconductor chip.

### SUMMARY

An embodiment of the inventive concept provides a semiconductor package configured to reduce a failure in a fabrication process.

According to an embodiment of the inventive concept, a semiconductor package may include a package substrate having a first surface and a second surface, which are opposite to each other, and including a trench formed in the first surface, a substrate pad provided on the package substrate to cover a bottom surface of the trench, a conductive coupling pattern in contact with a top surface of the substrate pad, an anisotropic conductive pattern provided on the conductive coupling pattern and the substrate pad to fill the trench, the anisotropic conductive pattern including conductive capsules and a polymer layer enclosing the conductive capsules, a semiconductor chip mounted on the first surface of the package substrate, and a coupling pillar pattern provided between the package substrate and the semiconductor chip and connected to the conductive coupling pattern in the trench. A top surface of the anisotropic conductive pattern may be coplanar with the first surface of the package substrate.

According to an embodiment of the inventive concept, a semiconductor package may include a package substrate having a first surface and a second surface, which are opposite to each other, and including a trench formed in the first surface, a substrate pad provided on the package substrate to cover a bottom surface of the trench, an anisotropic conductive pattern provided on the substrate pad to fill the trench, the anisotropic conductive pattern including conductive capsules including a first metal element and a polymer layer enclosing the conductive capsules, a semiconductor chip mounted on the first surface of the package substrate, a coupling pillar pattern provided between the package substrate and the semiconductor chip to penetrate the anisotropic conductive pattern and coupled to the substrate pad, and a conductive coupling pattern provided in the trench to be in contact with a bottom surface of the coupling pillar pattern and a top surface of the substrate pad. The conductive coupling pattern may include the first metal element.

According to an embodiment of the inventive concept, a semiconductor package may include a package substrate having a first surface and a second surface, which are opposite to each other, and including trenches, which are formed in the first surface and are spaced apart from each other, substrate pads formed in the trenches, respectively, conductive coupling patterns disposed on the substrate pads, respectively, anisotropic conductive patterns provided on the conductive coupling pattern and the substrate pad to fill the trenches, the anisotropic conductive patterns including conductive capsules and a polymer layer enclosing the conductive capsules, a semiconductor chip mounted on the first surface of the package substrate, an under-fill layer provided between the package substrate and the semiconductor chip to cover top surfaces of the anisotropic conductive patterns, a mold layer covering a top surface of the semiconductor chip and at least a portion of a top surface of the package substrate, coupling pillar patterns provided between the package substrate and the semiconductor chip to penetrate the under-fill layer and the anisotropic conductive patterns, respectively, and to be in contact with the conductive coupling patterns, respectively, and solder balls on the second surface of the package substrate. The top surfaces of the anisotropic conductive patterns may be coplanar with the first surface of the package substrate, and each of the conductive capsules and the conductive coupling patterns may include gallium (Ga).

### BRIEF DESCRIPTION OF THE DRAWINGS

FIG. 1 is a plan view illustrating a semiconductor package according to an example embodiment of the inventive concept.

FIG. 2 is a sectional view taken along a line I-I′ of FIG. 1.

FIG. 3A is an enlarged sectional view of a portion A of FIG. 2.

FIGS. 3B, 3C, and 3D are sectional views, each of which illustrates a portion (e.g., portion A of FIG. 2) of a semiconductor memory device according to an example embodiment of the inventive concept.

FIGS. 4, 5A, 5B, 6, 7A, and 7B are diagrams illustrating a method of fabricating a semiconductor memory device according to an example embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

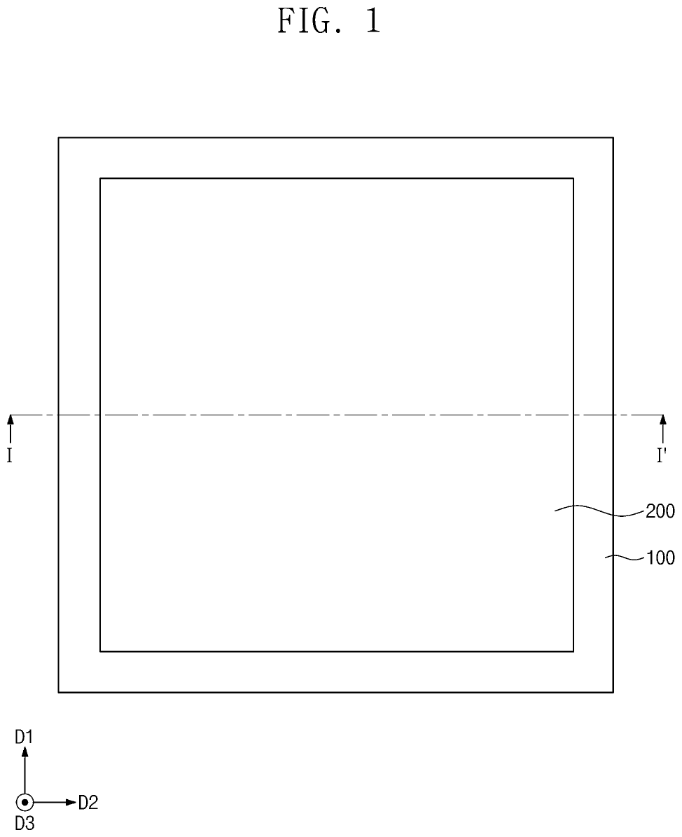

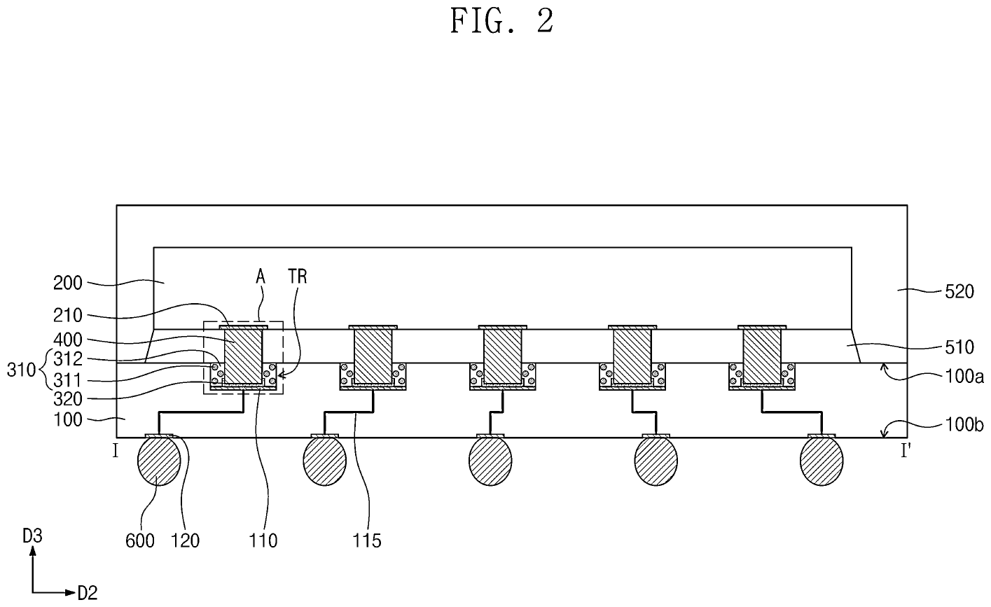

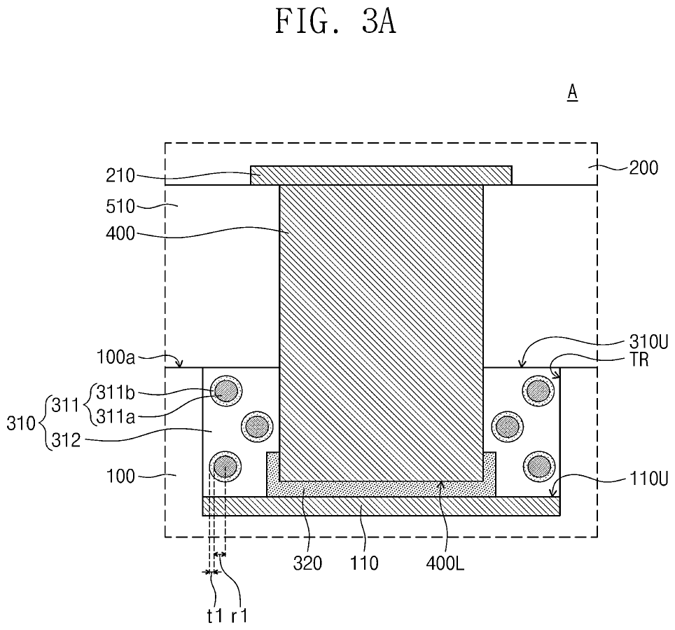

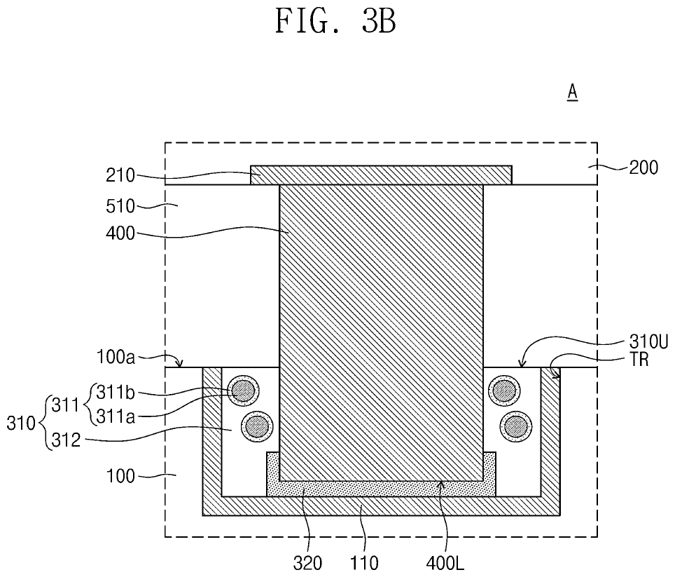

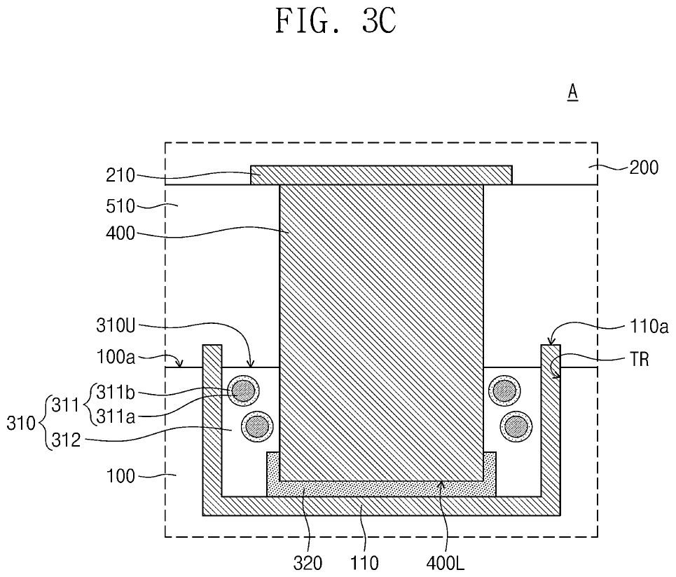

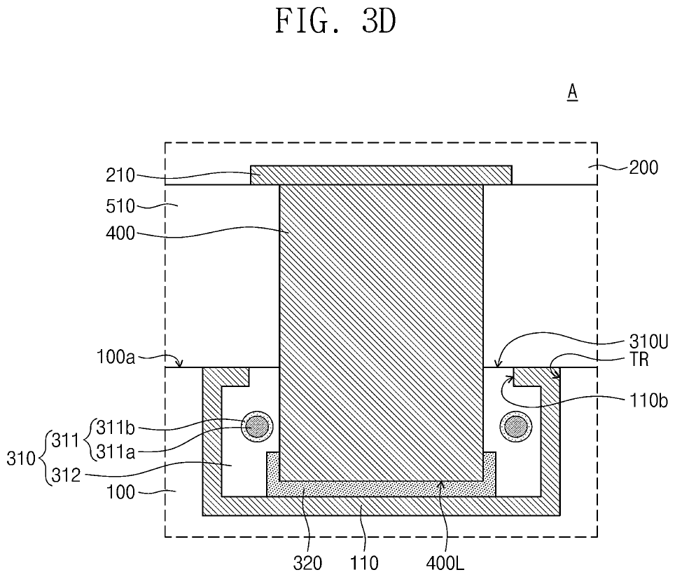

FIG. 1 is a plan view illustrating a semiconductor package according to an example embodiment of the inventive concept. FIG. 2 is a sectional view taken along a line I-I′ of FIG. 1. FIG. 3A is an enlarged sectional view of a portion A of FIG. 2.

Referring to FIGS. 1, 2, and 3A, a semiconductor package may include a package substrate 100, a semiconductor chip 200, an anisotropic conductive pattern 310, a conductive coupling pattern 320, a coupling pillar pattern 400, and an under-fill layer 510.

The package substrate 100 may include, for example, a printed circuit board (PCB). The package substrate 100 may have a first surface 100a and a second surface 100b, which are opposite to each other. For example, the first and second surfaces 100a and 100b of the package substrate 100 may mean top and bottom surfaces of the package substrate 100, respectively. Trenches TR may be formed in the package substrate 100 and near the first surface 100a to have a specific depth in a third direction D3. For example, the trenches TR may be recessed from the first surface 100a. In an embodiment, when viewed in a plan view, each of the trenches TR may have a circular shape and may be spaced apart from each other in a first direction D1 and a second direction D2. The trenches TR may be provided to have bottom surfaces that are lower than a top surface of the package substrate 100 without the trenches TR. The depth of the trenches TR may vary depending on the kind of the substrate. In the present specification, for convenience in description, the first surface 100a will be referred to a portion of the top surface of the package substrate 100, in which the trenches TR are not formed.

Substrate pads 110 may be provided in the trenches TR of the package substrate 100 to cover the bottom surfaces of the trenches TR. The substrate pads 110 may be placed in the trenches TR, respectively, which are formed near the first surface 100a. Bottom and side surfaces of the substrate pads 110 may contact bottom and side surfaces of the trenches TR. A top surface 110U of the substrate pad 110 may be located at a level that is lower than the first surface 100a of the package substrate 100. In an embodiment, the substrate pads 110 may be formed of or include at least one of metallic materials (e.g., copper, aluminum, nickel, gold, and/or tungsten).

The conductive coupling patterns 320 may be disposed on the substrate pads 110, respectively. The conductive coupling patterns 320 may be disposed between the substrate pads 110 and the coupling pillar patterns 400 corresponding thereto. For example, a top surface of the conductive coupling pattern 320 may cover a bottom surface 400L of the coupling pillar pattern 400, and a bottom surface of the conductive coupling pattern 320 may be in contact with the top surface 110U of the substrate pad 110. In an embodiment, the conductive coupling pattern 320 may include at least one protruding portion that is in contact with a portion of a side surface of the coupling pillar pattern 400. The top surface of the conductive coupling pattern 320 may be located at a level lower than the first surface 100a of the package substrate 100, and the entirety of the conductive coupling pattern 320 may be placed in the trench TR. In example embodiments, the conductive coupling pattern 320 may have a cup-shape.

The conductive coupling patterns 320 may include a metallic material different from the substrate pads 110. The conductive coupling patterns 320 may include a first metal element having a relatively low melting point. In this case, the conductive coupling patterns 320 may also have a relatively low melting point and thus may be formed at a low temperature environment, and the conductive coupling patterns 320 may be conductively coupled with the substrate pads 110 and the coupling pillar patterns 400. As an example, the melting point of the first metal element may range from 0° C. to 100° C. (in particular, from 10° C. to 30° C.), and in an embodiment, the first metal element may be gallium (Ga). The conductive coupling patterns 320 may be formed of or include an alloy containing gallium (Ga) and at least one of tin (Sn), indium (In), nickel (Ni), gold (Au), and zinc (Zn). The conductive coupling patterns 320 may be formed using conductive capsules 311, as will be described below, and in an embodiment, the conductive capsules 311 may include the first metal element, which is included in the conductive coupling pattern 320.

The coupling pillar patterns 400 may be disposed on the conductive coupling patterns 320, respectively. The coupling pillar pattern 400 may be provided between the semiconductor chip 200 and the package substrate 100 and may electrically connect the substrate pads 110 to corresponding chip pads 210. In the present specification, the expression “elements are electrically connected to each other” may mean that the elements are directly connected to each other or are indirectly connected to each other through another element. For example, the substrate pads 110 may be electrically connected to respective ones of the chip pads 210 through the conductive coupling patterns 320 and the coupling pillar patterns 400. In an embodiment, the coupling pillar patterns 400 may have a circular pillar shape, but the inventive concept is not limited to this example. A width of the coupling pillar pattern 400 may be smaller than a width of the substrate pad 110 or a width of the trench TR. A width of the coupling pillar pattern 400 may be smaller than a width of the conductive coupling pattern 320. In this case, it may be possible to reduce a difficulty in inserting the coupling pillar patterns 400 into the trenches TR. In an embodiment, the width of the coupling pillar pattern 400 or the substrate pad 110 may be a length of the coupling pillar pattern 400 or the substrate pad 110 measured in a direction (e.g., the first or second direction D1 or D2) perpendicular to the third direction D3. In an embodiment, the coupling pillar patterns 400 may be formed of or include at least one of metallic materials (e.g., copper, aluminum, nickel, gold, and/or tungsten).

The anisotropic conductive patterns 310 may be formed on the substrate pads 110 and the conductive coupling patterns 320. The anisotropic conductive patterns 310 may contact upper surfaces of the substrate pads 110, upper and side surfaces of the conductive coupling patterns 320, and side surfaces of the coupling pillar patterns 400. The anisotropic conductive patterns 310 may fill the trenches TR and may have top surfaces 310U that are substantially coplanar with the first surface 100a of the package substrate 100.

The anisotropic conductive pattern 310 may include the conductive capsules 311 and a polymer layer 312, which is provided to enclose the conductive capsules 311. The conductive capsules 311 may be dispersed in the polymer layer 312 in each of the trenches TR. Each of the conductive capsules 311 may include a conductor 311a and a cover layer 311b, which is formed to conformally cover the conductor 311a. In example embodiments, the cover layer 311b may surround the conductor 311a. For example, the cover layer 311b may entirely enclose the conductor 311a. The conductor 311a and the cover layer 311b may be provided to form a single spherical object. In an embodiment, a thickness t1 of the cover layer 311b may range from 1 nm to 10 μm, and a radius r1 of the conductor 311a in the cover layer 311b may range from 1 μm to 1 mm (i.e., 1 nm≤t1≤10 μm, 1 μm≤r1≤1 mm).

The conductor 311a may be present as a liquid metal under a room-temperature ambient-pressure condition, and the cover layer 311b may be a layer enclosing the conductor 311a, which is in the liquid state. The conductor 311a may include the same metal element (e.g., the first metal element) as the conductive coupling patterns 320, and in an embodiment, the conductive coupling patterns 320 may be formed through a thermocompression process on the conductive capsules 311. As described above, the melting point of the first metal element may range from 0° C. to 100° C. (in particular, from 10° C. to 30° C.), and in an embodiment, the first metal element may be gallium (Ga). The conductor 311a may be formed of or include an alloy containing gallium (Ga) and at least one of indium (In), tin (Sn), nickel (Ni), gold (Au), and zinc (Zn). The cover layer 311b may be a polymer layer, a metal layer, or a metal oxide layer, but the inventive concept is not limited to this example.

The polymer layer 312 may be formed of or include at least one of polymeric materials. For example, the polymer layer 312 may be formed of or include at least one of thermosetting or thermoplastic resins. As an example, the thermosetting resin may include epoxy, melamine-formaldehyde, urea-formaldehyde, or phenol-formaldehyde, and the thermoplastic resin may include polyvinyl chloride (PVC), polystyrene, polytetrafluoroethylene (PTFE), polypropylene, nylon, cellulose nitrate, cellulose acetate, acrylic (methacrylate), polyethylene, or acetal, but the inventive concept is not limited to these examples.

Referring back to FIG. 2, the under-fill layer 510 may be placed on the first surface 100a of the package substrate 100. The under-fill layer 510 may cover the first surface 100a of the package substrate 100 and the top surfaces 310U of the anisotropic conductive patterns 310. The under-fill layer 510 may be provided to cover top surfaces of the anisotropic conductive patterns 310 and to prevent the conductive capsules 311 of the anisotropic conductive patterns 310 from being moved out of the trench TR. Thus, the conductive capsules 311 may not be disposed in the under-fill layer 510. In an embodiment, the under-fill layer 510 may include an insulating polymer (e.g., epoxy).

Substrate lower pads 120 may be disposed on the second surface 100b of the package substrate 100. Bottom surfaces of the substrate lower pads 120 and the second surface 100b of the package substrate 100 may be coplanar. The substrate lower pads 120 may be electrically connected to the substrate pads 110, which are formed in the trenches TR of the package substrate 100, through an interconnection pattern 115 in the package substrate 100.

Solder balls 600 may be disposed on the second surface 100b of the package substrate 100. For example, the solder balls 600 may be disposed on the bottom surfaces of the lower pads 120, respectively, and may be coupled to the lower pads 120, respectively. In example embodiments, each solder ball 600 may contact a bottom surface of a corresponding one of the lower pads 120. The solder balls 600 may be electrically coupled to the substrate pads 110. The solder balls 600 may be electrically disconnected from each other. The solder balls 600 may include a solder material. For example, the solder materials may include tin, bismuth, lead, silver, or alloys thereof.

The semiconductor chip 200 may be mounted on the top surface of the package substrate 100. The semiconductor chip 200 may be a memory chip, a logic chip, or a buffer chip. The semiconductor chip 200 may include a semiconductor substrate (not shown), integrated circuits (not shown), and an interconnection layer (not shown). In an embodiment, the semiconductor substrate may include at least one of semiconductor materials (e.g., silicon, germanium, or silicon-germanium), and the integrated circuits may include transistors.

The chip pads 210 may be disposed on a surface of the semiconductor chip 200. For example, bottom surfaces of the chip pads 210 may be coplanar with a bottom surface of the semiconductor chip 200. The chip pad 210 may be in contact with a top surface of the coupling pillar pattern 400 and may be electrically connected to the substrate pad 110. In an embodiment, the chip pads 210 may include a metallic material (e.g., copper, aluminum, and/or tungsten).

A mold layer 520 may cover a top surface of the semiconductor chip 200. The mold layer 520 may cover the top and side surfaces of the semiconductor chip 200 and a portion of the top surface of the package substrate 100. The mold layer 520 may be formed of or include an insulating polymer (e.g., an epoxy molding compound).

Next, other example embodiments of the inventive concept will be described in more detail with reference to FIGS. 3B, 3C, and 3D. FIGS. 3B, 3C, and 3D are diagrams, each of which illustrates a portion (e.g., A of FIG. 2) of a semiconductor memory device according to another embodiment of the inventive concept. In the following description, a previously-described element may be identified by the same reference number without repeating an overlapping description thereof, for concise description.

Referring to FIG. 3B, each of the substrate pads 110 may conformally cover side and bottom surfaces of the trench TR. The substrate pads 110 may be extended to cover the side surface of the trench TR, unlike that shown in FIG. 3A. For example, the substrate pads 110 may contact the bottom and side surfaces of the trench TR. An end portion of the substrate pad 110, which is extended in the side surface of the trench TR, may be coplanar with the first surface 100a of the package substrate 100. The anisotropic conductive pattern 310 may cover top and side surfaces of the substrate pad 110 and may fill the trench TR. The under-fill layer 510 may contact an uppermost top surface of each of the substrate pads 110.

Referring to FIG. 3C, each of the substrate pads 110 may conformally cover the side and bottom surfaces of the trench TR. For example, the substrate pads 110 may contact the bottom and side surfaces of the trench TR. Furthermore, a portion of the substrate pad 110, which is in contact with the side surface of the trench TR, may be vertically extended toward the semiconductor chip 200 to form a protruding portion. For example, a protruding end portion 110a of the substrate pad 110 may be located at a level higher than the first surface 100a of the package substrate 100. The under-fill layer 510 may contact side and uppermost top surfaces of each of the substrate pads 110.

The anisotropic conductive pattern 310 may be in partial contact with the top and side surfaces of the substrate pad 110 and may fill the trench TR. The top surface 310U of the anisotropic conductive pattern 310 may be located at a level lower than the protruding end portion 110a of the substrate pad 110. Thus, the protruding end portion 110a of the substrate pad 110 may prevent the conductive capsules 311 in the trench TR from being moved into others of the trenches TR adjacent thereto, similar to the under-fill layer 510.

Referring to FIG. 3D, each of the substrate pads 110 may conformally cover the side and bottom surfaces of the trench TR. For example, each of the substrate pads 110 may contact the side and bottom surfaces of the trench TR. A portion 110b of the substrate pad 110 may be partially extended from a top end of the side surface of the trench TR in a direction parallel to the bottom surface of the package substrate 100 (e.g., in a direction perpendicular to the third direction D3 of FIG. 2). The anisotropic conductive pattern 310 may be in contact with the substrate pad 110 and may fill the trench TR.

The top surface 310U of the anisotropic conductive pattern 310 may be coplanar with the first surface 100a of the package substrate 100 and the uppermost top surface of the substrate pad 110. For example, a top surface of the portion 110b of the substrate pad 110 may be coplanar with the top surface 310U of the anisotropic conductive pattern 310 and the first surface 100a of the package substrate 100. In an embodiment, when viewed in a plan view, the top surface of the substrate pad 110 may be shaped like a ring and may partially veil the trench TR and the anisotropic conductive pattern 310. For example, the anisotropic conductive pattern 310 may contact a bottom surface of the portion 110b of the substrate pad 110. Thus, the top surface of the substrate pad 110 may prevent the conductive capsules 311 in the trench TR from being moved into others of the trenches TR adjacent thereto, similar to the under-fill layer 510.

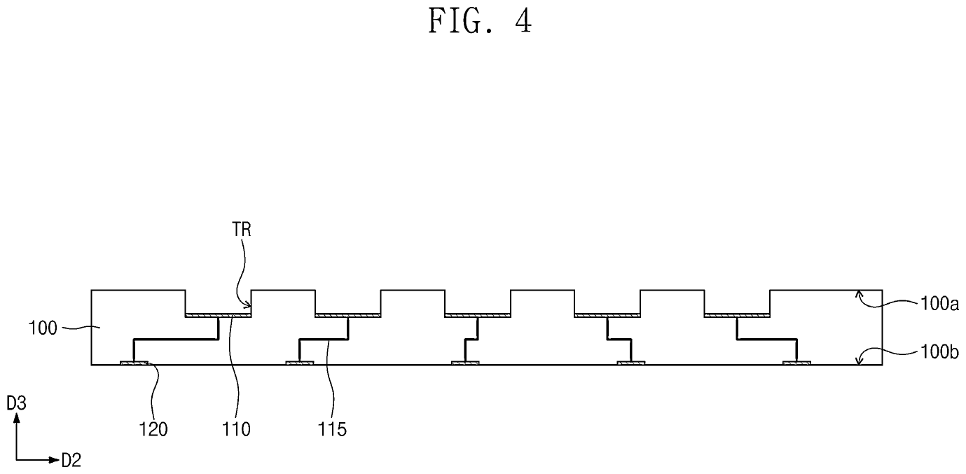

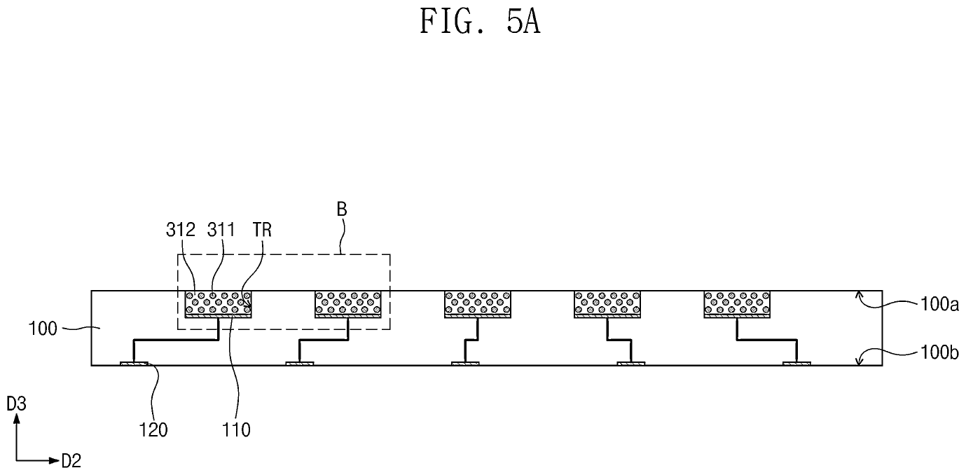

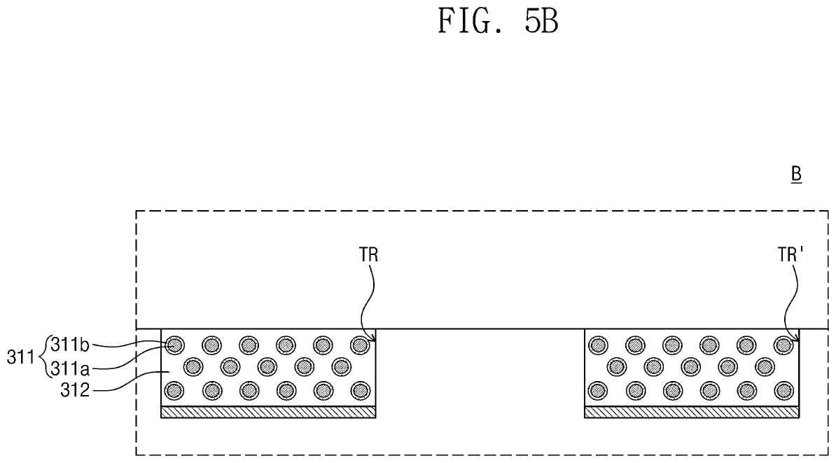

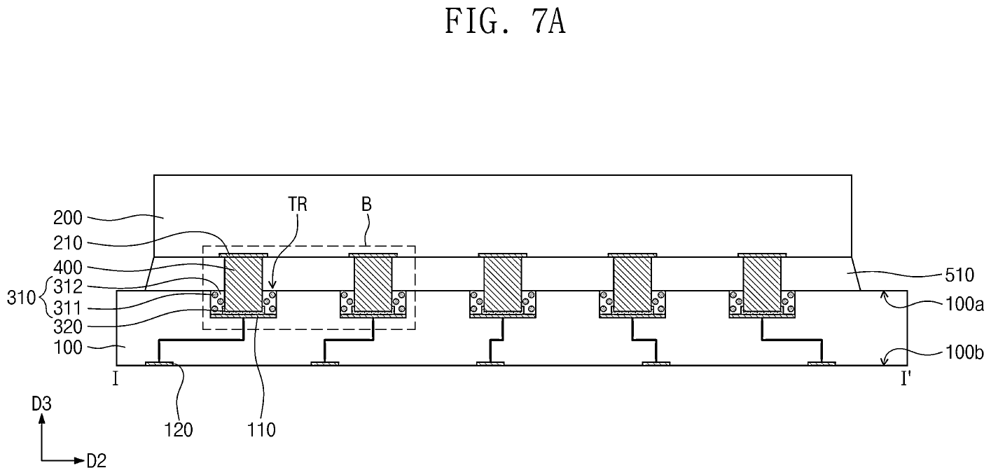

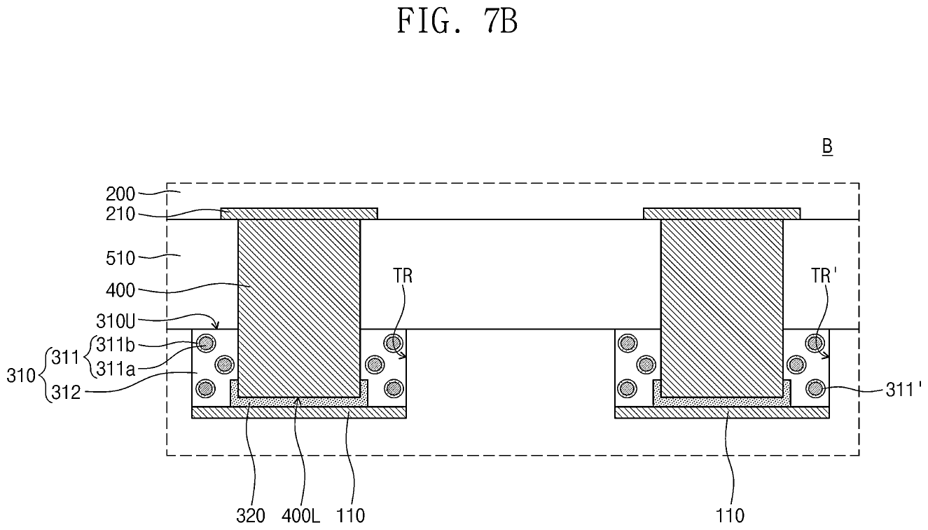

Hereinafter, a method of fabricating a semiconductor package according to an example embodiment of the inventive concept will be described in more detail with reference to FIGS. 4 to 7B. FIGS. 4, 5A, 5B, 6, 7A, and 7B are diagrams illustrating a method of fabricating a semiconductor memory device according to an example embodiment of the inventive concept. FIGS. 4, 5A, 6, and 7A are sectional views corresponding to the line I-I′ of FIG. 1. FIG. 5B is an enlarged sectional view illustrating a portion ‘B’ of FIG. 5A, and FIG. 7B is an enlarged sectional view illustrating a portion ‘B’ of FIG. 7A.

Referring to FIG. 4, the package substrate 100 with the trenches TR may be provided. The trenches TR may be formed by patterning the top surface of the package substrate 100. An interconnection pattern 115 may be provided in the package substrate 100, and the interconnection pattern 115 may be electrically connected to the substrate lower pads 120, which is disposed on the second surface 100b. The substrate pads 110 may be disposed in the trenches TR and may be electrically connected to the interconnection pattern 115 in the package substrate 100.

Referring to FIGS. 5A and 5B, the conductive capsules 311 and the polymer layer 312 may be formed to fill each of the trenches TR. For example, a polymer solution including the polymer layer 312 and the conductive capsules 311 therein may be formed, and then, a casting process may be performed to fill the trenches TR with the polymer solution. In an embodiment, as a result of the casting process, the conductive capsules 311 and the polymer layer 312 may be formed in only the trenches TR, and this may make it possible to reduce an amount of the conductive capsules 311 for this process and consequently to reduce the fabrication cost.

In an embodiment, the formation of the polymer solution may include stirring a conductive material (e.g., a first metal element or an alloy containing the same) and solvent using a stirring device, applying an ultrasonic wave to the conductive material and the solvent using an ultrasonic generator to disperse the conductive material, and supplying a monomer or a polymer material into the dispersed conductive material and the solvent to form the conductor 311a and the cover layer 311b enclosing the conductor 311a. In some cases, a cooling process or an aging process may be further performed to harden the cover layer 311b. The conductor 311a may be present as a liquid metal under a room-temperature ambient-pressure condition. As a result of the afore-described process, the conductive capsules 311, each of which includes the conductor 311a and the cover layer 311b, and the polymer layer 312, which encloses the conductive capsules 311, may be formed, as shown in FIGS. 5A and 5B. Here, the conductors 311a in the conductive capsules 311 may be separated from the polymer layer 312 by the cover layer 311b. In an embodiment, the size of the conductor 311a and/or the thickness of the cover layer 311b may be adjusted by changing a stirring speed, an intensity of the ultrasonic wave, and the kind of the solution. The conductor 311a may be formed of or include an alloy containing gallium (Ga) and at least one of indium (In), tin (Sn), nickel (Ni), gold (Au) and zinc (Zn). The cover layer 311b may be a polymer layer, a metal oxide layer, or the like, but the inventive concept is not limited to this example. For example, the polymer solution may be formed to fill the trenches TR, and the polymer solution may be hardened through a drying process.

In the step of filling the trenches TR with the polymer solution, if the polymer solution is excessively supplied, a portion of the polymer solution may be overflown to the first surface 100a of the package substrate 100. According to an embodiment of the inventive concept, the trenches TR and TR′ may be spaced apart from each other, and the conductive capsules 311 and the polymer layer 312 may be disposed in each of the trenches TR and TR′. In this case, the hardened polymer or the conductive capsules 311 may be left on the first surface 100a of the package substrate 100, after the drying process. After the drying process of the polymer solution, the hardened polymer and the conductive capsules 311 may be removed from the first surface 100a of the package substrate 100 such that the conductive capsules 311 are absent on the first surface 100a of the package substrate 100. In this case, the top surface of the polymer layer 312 and the first surface 100a of the package substrate 100 may be coplanar with each other.

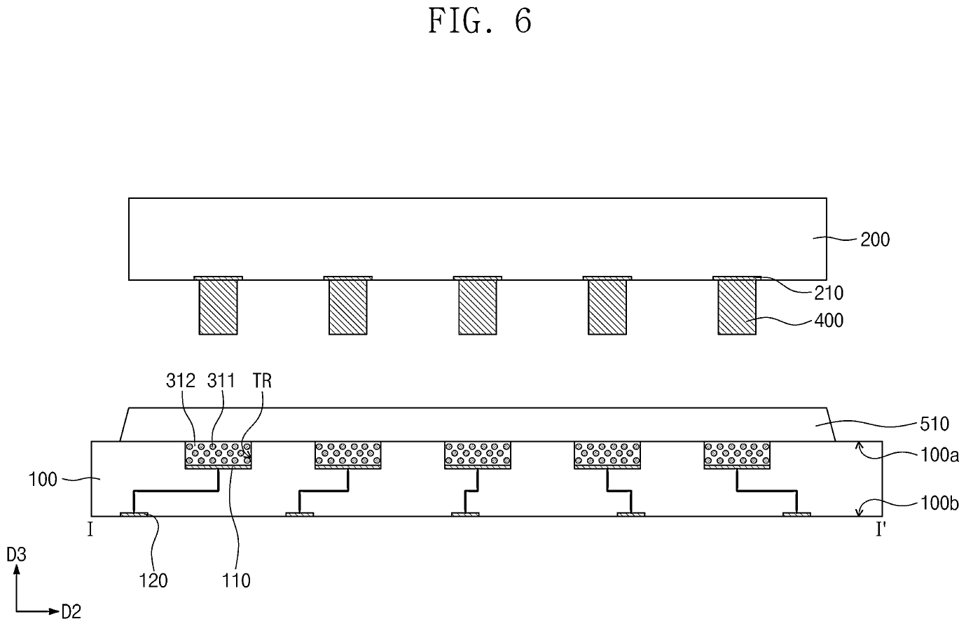

Referring to FIG. 6, the under-fill layer 510 may be disposed on the trenches TR and the package substrate 100. The under-fill layer 510 may cover the top surfaces of the trenches TR and a portion of the top surface of the package substrate 100. Here, the under-fill layer 510 may confine the polymer layer 312 and the conductive capsules 311 within the trenches TR.

Thereafter, the semiconductor chip 200 may be disposed on the under-fill layer 510 such that the coupling pillar patterns 400 on the semiconductor chip 200 are precisely placed over the trenches TR, respectively.

Referring to FIGS. 7A and 7B, the coupling pillar patterns 400 may penetrate the under-fill layer 510 and may be connected to the substrate pads 110 in the trenches TR. In the process of connecting the coupling pillar patterns 400 to the substrate pads 110, some of the conductive capsules 311 in the trenches TR may be compressed by the coupling pillar patterns 400. In this process, heat may be applied to the conductor 311a of the conductive capsules 311 to the extent of liquefying the conductor 311a of the conductive capsules 311. The conductor 311a may include a metallic material having a relatively low melting point, as described above, and in this case, it may be possible to prevent the semiconductor chip 200 adjacent thereto from being exposed to a high temperature environment.

Next, the cover layer 311b of the conductive capsules 311 may be damaged during the thermocompression process, and in this case, the conductors 311a may be in a liquid state and may be leaked from the cover layer 311b. The leaked conductors 311a may cover not only the bottom surface 400L of the coupling pillar pattern 400 but also a portion of the top surface of the substrate pad 110. Thereafter, the leaked conductors 311a may be hardened to form the conductive coupling pattern 320, and the coupling pillar pattern 400 and the substrate pad 110 may be electrically connected to each other through the conductive coupling pattern 320.

According to an embodiment of the inventive concept, the trenches TR and TR′ may be spaced apart from each other, and the conductive capsules 311 and the conductive coupling pattern 320 may be disposed in each of the trenches TR and TR′ that are spaced apart from each other. In other words, the conductive capsules 311 and 311′ may be absent between the trenches TR and TR′, and when the conductive coupling pattern 320 is formed through the thermocompression process, it may be possible to perfectly separate the conductive coupling pattern 320 in the trench TR electrically from the conductive coupling patterns 320 in the trench TR′ adjacent thereto.

Referring back to FIGS. 2 and 3A, the mold layer 520 may be disposed on the semiconductor chip 200. The solder balls 600 may be formed on bottom surfaces of the substrate lower pads 120.

According to an embodiment of the inventive concept, a semiconductor package may include a package substrate with trenches and an anisotropic conductive pattern in the trench, and here, the anisotropic conductive pattern may include a polymer layer and conductive capsules in the polymer layer. The conductive capsules may be locally provided within each of the trenches, not in a region between the trenches. Thus, in a thermocompression process, which is performed on the conductive capsules to form conductive coupling patterns, it may be possible to prevent adjacent ones of the conductive coupling patterns from being electrically connected to each other. Accordingly, it may be possible to reduce a failure in a process of fabricating or using the semiconductor package. In addition, the consumption amount of the conductive capsules may be reduced, and this may make it possible to reduce the fabrication cost of the semiconductor package.

In addition, the conductive capsules may have a lower melting point than a solder ball. In this case, the conductive coupling patterns may be formed at a relatively low temperature, and thus, the semiconductor chip and the package substrate may not be exposed to a high-temperature environment. This may make it possible to improve the reliability of the semiconductor package.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a package substrate having a first surface and a second surface, which are opposite to each other, and comprising a trench formed in the first surface;
a substrate pad provided on the package substrate to cover a bottom surface of the trench;
a conductive coupling pattern in contact with a top surface of the substrate pad;
an anisotropic conductive pattern provided on the conductive coupling pattern and the substrate pad to fill the trench, the anisotropic conductive pattern comprising conductive capsules and a polymer layer enclosing the conductive capsules;
a semiconductor chip mounted on the first surface of the package substrate; and
a coupling pillar pattern provided between the package substrate and the semiconductor chip and connected to the conductive coupling pattern in the trench,
wherein a top surface of the anisotropic conductive pattern is coplanar with the first surface of the package substrate.

2. The semiconductor package of claim 1, wherein each of the conductive capsules and the conductive coupling pattern comprises gallium (Ga).

3. The semiconductor package of claim 2, wherein the conductive capsules and the conductive coupling pattern further comprises at least one of indium (In), tin (Sn), nickel (Ni), gold (Au), or zinc (Zn).

4. The semiconductor package of claim 1,
wherein each of the conductive capsules comprises a conductor and a cover layer enclosing the conductor, and
wherein a melting point of the conductor ranges from 10° C. to 30° C.

5. The semiconductor package of claim 4, wherein the cover layer comprises at least one of a polymer layer and a metal oxide layer.

6. The semiconductor package of claim 1, further comprising:
an under-fill layer provided between the package substrate and the semiconductor chip to cover the top surface of the anisotropic conductive pattern; and
a mold layer covering a top surface of the semiconductor chip and a portion of a top surface of the package substrate.

7. The semiconductor package of claim 1, wherein a width of the coupling pillar pattern is smaller than a width of the substrate pad.

8. The semiconductor package of claim 1, wherein the top surface of the substrate pad is located at a level lower than the first surface of the package substrate.

9. The semiconductor package of claim 1, wherein the substrate pad is provided to cover the bottom surface of the trench and a side surface of the trench.

10. The semiconductor package of claim 9, wherein the substrate pad comprises a protruding portion that is extended to a level higher than the first surface of the package substrate.

11. The semiconductor package of claim 9, wherein the top surface of the substrate pad has a ring shape, when viewed in a plan view.

12. A semiconductor package, comprising:
a package substrate having a first surface and a second surface, which are opposite to each other, and comprising a trench formed in the first surface;
a substrate pad provided on the package substrate to cover a bottom surface of the trench;
an anisotropic conductive pattern provided on the substrate pad to fill the trench, the anisotropic conductive pattern comprising conductive capsules including a first metal element and a polymer layer enclosing the conductive capsules;
a semiconductor chip mounted on the first surface of the package substrate;
a coupling pillar pattern provided between the package substrate and the semiconductor chip to penetrate the anisotropic conductive pattern and coupled to the substrate pad; and
a conductive coupling pattern provided in the trench to be in contact with a bottom surface of the coupling pillar pattern and a top surface of the substrate pad,
wherein the conductive coupling pattern comprises the first metal element.

13. The semiconductor package of claim 12,
wherein each of the conductive capsules comprises a conductor and a cover layer enclosing a surface of the conductor, and
wherein the conductor comprises the first metal element.

14. The semiconductor package of claim 12, wherein a melting point of the first metal element ranges from 10° C. to 30° C.

15. The semiconductor package of claim 12, wherein the first metal element comprises gallium (Ga).

16. The semiconductor package of claim 12, further comprising:
an under-fill layer provided between the package substrate and the semiconductor chip to cover a top surface of the anisotropic conductive pattern; and
a mold layer covering a top surface of the semiconductor chip and a portion of a top surface of the package substrate.

17. The semiconductor package of claim 12, wherein a top surface of the conductive coupling pattern is located at a level that is lower than the first surface of the package substrate.

18. The semiconductor package of claim 12, wherein the substrate pad is provided to cover the bottom surface of the trench and a side surface of the trench.

19. The semiconductor package of claim 12, wherein the substrate pad comprises a protruding portion that is extended to a level higher than the first surface of the package substrate.

20. A semiconductor package, comprising:
a package substrate having a first surface and a second surface, which are opposite to each other, and comprising trenches, which are formed in the first surface and are spaced apart from each other;
substrate pads formed in the trenches, respectively;
conductive coupling patterns disposed on the substrate pads, respectively;
anisotropic conductive patterns provided on the conductive coupling pattern and the substrate pad to fill the trenches, the anisotropic conductive patterns comprising conductive capsules and a polymer layer enclosing the conductive capsules;
a semiconductor chip mounted on the first surface of the package substrate;
an under-fill layer provided between the package substrate and the semiconductor chip to cover top surfaces of the anisotropic conductive patterns;
a mold layer covering a top surface of the semiconductor chip and at least a portion of a top surface of the package substrate;
coupling pillar patterns provided between the package substrate and the semiconductor chip to penetrate the under-fill layer and the anisotropic conductive patterns, respectively, and to be in contact with the conductive coupling patterns, respectively; and
solder balls on the second surface of the package substrate,
wherein the top surfaces of the anisotropic conductive patterns is coplanar with the first surface of the package substrate, and
wherein each of the conductive capsules and the conductive coupling patterns comprises gallium (Ga).
